(19) United States
(12) Patent Application Publication
(10) Pub. No.: US 2026/0291452 A1
(43) Pub. Date: Sep. 24, 2026

(54) SWITCHING AMPLIFIERS

(71) Applicant: Cirrus Logic International Semiconductor Ltd., Edinburgh (GB)

(72) Inventors: John Paul LESSO, Edinburgh (GB); John L. MELANSON, Austin, TX (US)

(73) Assignee: Cirrus Logic International Semiconductor Ltd., Edinburgh (GB)

(21) Appl. No.: 19/084,405

(22) Filed: Mar. 19, 2025

(51) Int. Cl. H03F 3/217; H03F 1/02

(52) U.S. Cl. CPC H03F 3/2173; H03F 1/0227; H03F 2200/03

(57) ABSTRACT

This application relates to methods and apparatus for controlling a switching amplifier to drive a load with a differential drive signal based on an input signal, where the switching amplifier operates to modulate first and second output nodes between switching voltages to generate the differential drive signal. The switching voltages are selected as neighbouring switching voltages from a set of at least three different switching voltages, where a voltage difference between at least one pair of neighbouring switching voltages is different to that of another pair of neighbouring switching voltages. The controller is configured to control the modulation of the output nodes to dynamically control a common-mode voltage applied to the output nodes based on an indication of amplitude of the input signal.

### FIELD OF DISCLOSURE

The field of representative embodiments of this disclosure relates to methods, apparatus and/or implementations concerning or relating to switching amplifiers, i.e. to switched-mode drivers such as class-D amplifiers or the like.

### BACKGROUND

Switching amplifiers, also called switched-mode amplifiers, such as class-D amplifiers and the like, are used in a variety of applications for driving load transducers, such as audio output transducers or the like, and can have advantages in terms of power efficiency compared to linear amplifiers. Class-D amplifiers typically comprise an output stage for modulating at least one output node between defined switching voltages with a duty-cycle such that the average voltage, over the course of one or more switching cycles, has the desired level.

Class-D amplifiers may often be implemented to drive the load transducer in a bridge-tied-load (BTL) configuration, and thus the load may be connected between first and second output nodes, each of which is modulated between defined switching voltages to generate the desired differential driving voltage across the load (on average across the switching cycle).

In some examples, each of the first and second output nodes may be modulated between two defined switching voltages that do not substantially vary in use, e.g. between a high-side voltage VH and a low-side voltage VL defining an input voltage Vin=VH−VL. In this case, by appropriate control of the duty cycle of modulation of on both sides of the load, a differential drive signal in the range of +Vin to −Vin may be developed across the load. In some applications, however, e.g. for relatively high-power applications, the magnitude of the input voltage Vin, i.e. the voltage difference between the high-side voltage and the low-side voltage, may need to be relatively high to be able to achieve the desired output range for the differential drive signal. Continually switching each output node between two switching voltages with a relatively large voltage difference between them can lead to issues with EMI (electromagnetic interference) and also power losses. In addition, if the voltage difference between the high-side voltage VH and the low-side voltage VL is large, so as to provide a relatively large output range, then, for small signal levels the duty-cycle (in terms of the proportion of the switching cycle spent at the high-side voltage VH) may be quite small, and the impact of timing errors may be relatively large, which can be challenging for some modulator designs.

In at least some applications, in particular for relatively high-power applications and/or in applications where there may be a relatively long output path between the output stage and the load, such as automotive or home theatre applications, there may be an output filter for filtering applying filtering to the output of the amplifier so as to provide the drive signal for the load. Such an output filter may typically be implemented by an inductance-capacitance (LC) filter, with a series inductance in the output path and a shunt capacitance to a defined voltage, such as ground. Switching the output nodes between switching voltages with a relatively large voltage difference between them can lead to a relatively large ripple current in the inductor and resultant inductor losses may be significant.

To mitigate this problem, multi-level switching amplifiers have been proposed, in which the switching voltages used for modulating the output nodes may be dynamically varied in use based on the amplitude of differential output signal. For instance, as well the high-side and low-side voltages VH and VL there may be at least one intermediate voltage VM which is a voltage between the high-side voltage VH and the low-side voltage VL. For example, the high-side voltage VH could be a supply voltage VDD, the low-side voltage could be ground and the intermediate voltage VM could be between the high-side and low-side voltages, say VDD/2 for example, although other values for the intermediate voltage could be used.

In this case, there are various different modulation schemes that may be used. In a modulation scheme based on AD modulation, the input signal may effectively be compared to a carrier waveform to generate a PWM control signal for controlling modulation of one output node, with the PWM control signal effectively being inverted for controlling modulation of the other output node. This results in the output nodes effectively being modulated in antiphase, such that there is always an instantaneous differential voltage across the load. To make use of the different switching voltages, the switching driver may be effectively operated in different modes which use different pairs of switching voltages. For instance, when the required differential drive signal has a relatively high amplitude, e.g. with an amplitude from about VDD/2 to VDD, the switching amplifier may operate in a first mode, which may be seen as a high-level mode, and may modulate the output nodes between the high-side and low-side voltages, e.g. between VDD and ground. However, if the differential drive signal is in a low amplitude range, e.g. with an amplitude lower than VDD/2, the switching amplifier may operate in a second mode, which may be seen as a low-level mode, and may modulate each of the output nodes between the intermediate voltage and the low-side voltage, i.e. between VDD/2 and ground. Operating in the second, low-level mode, reduces the voltage difference of the modulation of the output nodes, with consequent advantages for EMI and power loss and the use of the second, low-level mode at low signal levels can ease modulator design requirements. However, when operating in the high-level mode, the output nodes are switched between the supply voltages and so there may still be significant EMI and power consumption.

An alternative modulation approach is based on BD modulation, which effectively modulates the first and second output nodes independently to provide the desired differential voltage. This allows both output nodes to be driven to the same switching voltage at the same time which thus can provide a differential voltage of zero across the load for part of the switching cycle. In use, the first output node may also be modulated between different switching voltages to the second output node. For instance, to generate a differential output voltage of one polarity, e.g. positive, the first output node may be modulated between VDD and VDD/2 whilst the second output node is modulated between VDD/2 and ground and to generate a differential output voltage of the opposite polarity, e.g. negative, the first output node is modulated between VDD/2 and ground whilst the second output node is modulated between VDD and VDD/2. In this way the whole output range of differential drive signals from +VDD to −VDD can be generated with each output node only being modulated between voltages that differ by VDD/2, which can be advantageous in terms of reduced EMI and power losses.

In this example where the intermediate voltage is halfway between the high-side and low-side voltages, for signals at or near zero, each of the first and second output nodes will be driven to the intermediate voltage for most or all of the switching cycle, which can lead to a low ripple current which can also provide power savings in reduced core losses.

In some implementations, however, it may not be practical or convenient to provide an intermediate voltage which is halfway between the high-side and low-side voltages, and, in such a case, conventional BD modulation techniques may involve some relatively significant power losses.

### SUMMARY

Embodiments of the present disclosure relate to methods and apparatus for multi-level switching amplifiers that at least mitigate at least some of above-mentioned issues.

According to an aspect of the disclosure there is provided a controller for controlling an output stage of a switching amplifier to drive a load connected between first and second output nodes with a differential drive signal based on an input signal. The controller is configured to be operable to control the output stage to modulate each of first and second output nodes between respective selected switching voltages in switching cycles to generate the differential drive signal, wherein the selected switching voltages are neighbouring switching voltages selected from a set of at least three different switching voltages and wherein a voltage difference between at least one pair of neighbouring switching voltages of the set is different to a voltage difference between at least one other pair of neighbouring switching voltages of the set. The controller is further configured to control the modulation of the first and second output nodes to dynamically control a common-mode voltage applied to the first and second output nodes based on an indication of amplitude of the input signal.

In some implementations, the controller may be configured to be operable to control the common-mode voltage to have a first value for an input signal amplitude which is zero, where the first value is not equal to a midpoint voltage value which is midway between the highest and lowest voltages of the set of at least three switching voltages. The first value may be selected such that the extent of a ripple current generated by modulating the first and second output nodes with the first value of common-mode voltage is lower than a ripple current that would be generated by modulating the first and second output nodes with a common-mode voltage equal to the midpoint voltage value. In some implementations, the controller may be configured, for at least a first range of non-zero input signal amplitude, to dynamically vary the common-mode voltage with variation in input signal amplitude. The controller may be configured to vary the common-mode voltage so that the differential drive signal based on the input signal can be generated without clipping. The controller may be configured to limit the rate of change of the common-mode voltage to not exceed a maximum rate of change. The controller may be configured to apply signal limiting to the input signal so as to limit any increase in signal amplitude that would require a rate of change of the common-mode voltage that would exceed a maximum rate of change. The controller may receive a look-ahead indication of what the input signal amplitude will be and is configured to dynamically vary the common-mode voltage based on said look-ahead indication.

The controller may be further configured to control the common-mode voltage applied to the first and second output nodes based on a power budget for power draw from a first power supply for providing one of the switching voltages of the set. The controller may be configured to receive an indication of loading of the first power supply. The first value of common-mode voltage may be selected such that modulating the first and second output nodes with the first value of common-mode voltage for an input signal of zero amplitude results in power being drawn from the first power supply and the controller may be further operable to control the common-mode voltage to have a second, different, value for an input signal amplitude which is zero, wherein the second value of common-mode voltage is selected such that modulating the first and second output nodes with the second value of common-mode voltage for an input signal of zero amplitude results in substantially no power being drawn from the first power supply.

In some examples, the set of at least three switching voltages may comprise at least a first voltage V1, a second voltage V2 and third voltage V3, wherein V1>V2>V3 and V2 is closer to V3 than V1. The controller may be configured to be operable to control the common-mode voltage to have a first value for an input signal amplitude which is zero, where the first value is between V2 and V3. In some examples, the first value may be midway between V2 and V3. In other examples, the first value may be closer to V2 than to V3. In some implementations the controller may be configured, for a first range of input signal amplitude, to dynamically vary the common-mode voltage with variation in input signal amplitude so to reduce the common-mode voltage from the first value to a second value with increasing signal amplitude, where the second value is equal to or greater than a voltage midway between V2 and V3; and for a second range of greater input signal amplitude, the controller may be configured to dynamically vary the common-mode voltage with variation in input signal amplitude so to increase the common-mode voltage from the second value to a third value with increasing signal amplitude, where the third value is equal to a voltage midway between V1 and V3.

Aspects also relate to a switching amplifier circuit comprising the controller of any of the embodiments described herein and an output stage.

In a further aspect there is provided a controller for controlling an output stage of a switching amplifier to drive a load connected between first and second output nodes with a differential drive signal based on an input signal where, the controller is configured to be operable to control the output stage to modulate each of first and second output nodes between respective selected switching voltages of a set of at least three switching voltages in switching cycles to generate the differential drive signal. The controller is further configured to control the modulation of the first and second output nodes so to dynamically vary a common-mode voltage applied to the first and second output nodes with input signal amplitude over at least a first range of input signal amplitude.

In a further aspect there is provided a controller for controlling an output stage of a switching amplifier to drive a load connected between first and second output nodes with a differential drive signal based on an input signal, where the controller is configured to be operable to control the output stage to modulate each of first and second output nodes between respective selected switching voltages of a set of at least three switching voltages in switching cycles to generate the differential drive signal, and the controller is configured to control the modulation of the first and second output nodes so to dynamically vary a common-mode voltage applied to the first and second output nodes based on a power budget for power draw from a first power supply for providing one of the switching voltages of the set of at least three switching voltages.

In a further aspect there is provided a controller for controlling a multichannel driver having a plurality of channels, each channel comprising a respective switching amplifier for driving a respective load connected between respective first and second output nodes with a respective differential drive signal based on a respective input signal, where the controller is configured to be operable to control each switching amplifier to modulate each of first and second output nodes between respective selected switching voltages of a set of at least three switching voltages in switching cycles to generate the differential drive signal, and the controller is configured to control at least one of the switching amplifiers so to dynamically vary a common-mode voltage applied to the respective first and second output nodes to control an overall power draw from a first power supply for providing one of the switching voltages of the set of at least three switching voltages from all of the switching amplifiers.

It should be noted that, unless expressly indicated to the contrary herein or otherwise clearly incompatible, then any feature described herein may be implemented in combination with any one or more other described features.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 illustrates one example of a multilevel switching amplifier for driving a load in BTL configuration;

FIG. 2 illustrates an example of a convention BD modulation scheme of the switching amplifier illustrated in FIG. 1;

FIG. 3 illustrates example switching waveforms for the switching amplifier of FIG. 1 controlled according to the modulation scheme of FIG. 2;

FIG. 4 Illustrates a plot of inductor losses against voltage demand;

FIG. 5 illustrates example switching waveforms for the switching amplifier of FIG. 1 controlled according to a modulation scheme of an embodiment;

FIG. 6 illustrates an example of a switch controller according to an embodiment;

FIG. 7 illustrates an example transfer characteristic between signal amplitude and common-mode voltage;

FIG. 8 illustrates example switching waveforms for the switching amplifier of FIG. 1 controlled according to a modulation scheme of another embodiment

FIG. 9 illustrates an amplifier system according to an embodiment;

FIG. 10 illustrates further example transfer characteristics between signal amplitude and common-mode voltage;

FIG. 11 illustrates an example of a four-level switching amplifier; and

FIG. 12 illustrates a plot of inductor losses against voltage demand for switching amplifier of FIG. 11.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Embodiments of the disclosure relate to multi-level switching amplifiers, i.e. switching amplifiers in which amplifier output nodes may be modulated between switching voltages to generate a desired output voltage, on average over the course of one or switching cycles, and where the switching voltages used for modulating the output nodes may be dynamically varied in use.

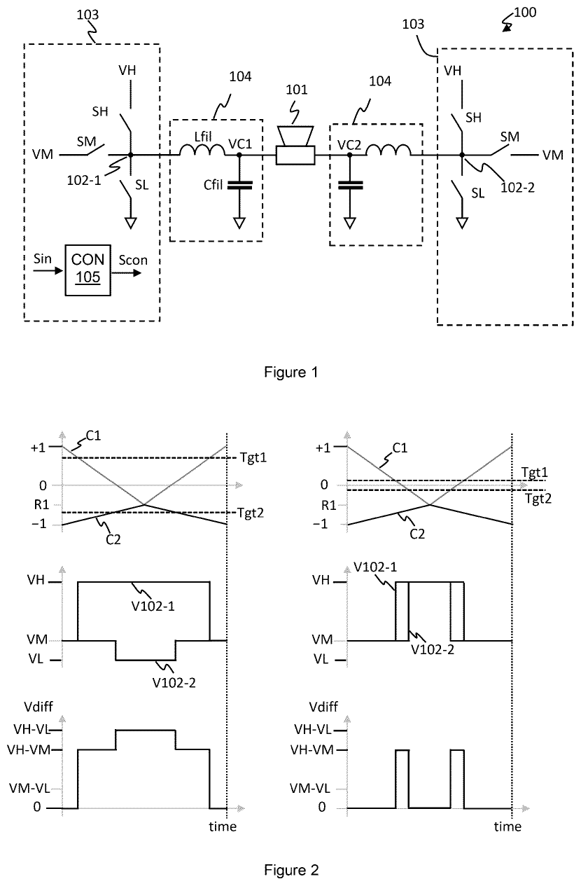

FIG. 1 illustrates one example of a multi-level switching amplifier 100 for driving a load 101. The switching amplifier 100 is configured to drive the load 101, which, in this example, is an audio transducer (but which in other examples could be other types of transducer), in a bridge-tied-load (BTL) configuration and thus, in use, the load 101 is connected between first and second output nodes 102-1 and 102-2 of an output stage 103 of the switching amplifier 100.

In at least some implementations, there may be an output filter 104 for applying filtering in the respective output path from each output node 102-1 and 102-2 to the load. As will be understood by one skilled in the art, for some applications, some filtering in the output path may be important, for instance for relatively high-power applications, e.g. for driving an output power of 10 W or greater, and/or where the output path between the output nodes 102-1 and 102-2 of the switching amplifier 100 and the load 101 may be relatively long, e.g. of the order of tens of centimetres or greater. For example, audio systems in automotive applications and home theatre and the like may typically be required to output relatively high output powers and may have output paths of the order of tens of centimetres to meters between the switching driver and the loudspeaker being driven and, in such applications, filtering of the output path may be important. Typically, each output filter 104 may comprise an LC (inductance-capacitance) filter which is separate to the load 101. FIG. 1 illustrates one example of a basic filter 104 with a series inductance Lfil in the output path and capacitance Cfil between the output path and a defined reference voltage, such as ground, on each side of the load. Other LC filter arrangements may be implemented, however, as would be understood be one skilled in the art. Where the output stage 103 of the switching amplifier 100 is implemented as an integrated circuit, the respective output filters 104 may be implemented, at least partly by external components, i.e. components which are off chip and not part of the integrated circuit.

The output stage 103 is operable such that the first and second output nodes 102-1 and 102-2 can be selectively connected to a high-side voltage VH, e.g. a supply voltage, and to a low-side voltage, which in this example is ground. In the example of FIG. 1, these connections are provided by switches SH and SL respectively. In addition, each of the first and second output nodes 102-1 and 102-2 can be selectively connected to an intermediate voltage VM, where the intermediate voltage is a voltage at a level which is between the high-side voltage and low-side voltage. In the example of FIG. 1 the connection between the relevant output node 102-1 or 102-2 and the intermediate voltage VM is via a respective switch SM.

This switching arrangement, where an output node can be selectively connected to three different voltages by respective switching paths is often referred to as a T-bridge or a Y-bridge and shall be referred to herein as a T-bridge, although it should be understood that this is just a convenient label and nothing should be implied about the physical layout of the switching paths by use of the term T-bridge. The output stage 103 of the example of FIG. 1 thus comprises first and second T-bridges for modulating the first and second output nodes 102-1 and 102-2 respectively.

In use, a switch controller 105 controls the switching of the T-bridges of the output stage 103 based on an input signal Sin, so as to modulate the voltages of the output nodes in a switching cycle that generates the desired differential output voltage across the load, on average over the course of the switching cycle.

In the example of FIG. 1, the switch controller 105 may be operable to control the modulation according to a BD type modulation scheme. In such a modulation scheme, each of the first and second output nodes 102-1 and 102-2 may be selectively modulated between the high-side voltage VH and the intermediate voltage VM or between the intermediate voltage VM and the low-side voltage VL, i.e. ground in this example. In the other words, the output nodes are modulated between neighbouring voltages in the set of (in this case) three different possible switching voltages. By neighbouring voltages in the set is meant a first voltage and the first which is either next highest (i.e. more positive) or lowest (i.e. less positive) in the set. Thus, the low-side voltage is a neighbouring voltage to the intermediate voltage VM (and vice-versa), and the low-side voltage is a neighbouring voltage to the intermediate voltage VM (and vice-versa), but the low-side and high-side voltages are not neighbouring voltages in the set as the intermediate voltage lies between them.

For such a BD modulation scheme, the intermediate voltage VM may, when possible, usefully be set to half-way between the high-side and low-side voltage VH and VL, e.g. if the high-side voltage VH is a supply voltage VDD and the low-side voltage VL is ground, the intermediate voltage VM may be set to VDD/2. This provides a balanced arrangement, in which modulating an output node between the high-side voltage VH and the intermediate voltage VM involves the same change in voltage as modulating between the intermediate voltage VM and low-side voltage VL, e.g. VDD/2. The quiescent signal output level will also typically correspond to each output node being driven to a voltage midway between the high-side and low-side voltage VH and VL and so, in this case, the quiescent signal level corresponds to each output node being driven to the intermediate voltage VM for the whole of the switching cycle.

In some cases, however, it may not be possible or practical to provide the intermediate voltage VM at a level which is midway between the high-side and low-side voltages. In this unbalanced case (i.e. where the voltage difference between VH and VM is different to the voltage difference between VM and VL), the conventional approach to BD modulation would again be to set the quiescent signal level to be equal to halfway between the high-side and low-side voltages VH and VL, and to control modulation of the first and second output nodes 102-1 and 102-2 so as to apply equal and opposite variations in voltage from this quiescent signal level to generate the desired drive signal. In other words, the common-mode component of the output of the switching amplifier 100 would be set at a point which is halfway between the high-side and low-side voltages, such that the differential signal component can vary with the full output range.

FIG. 2 illustrates one example of a modulation scheme based on conventional BD modulation and illustrates examples of the resultant switching waveforms for two different input signal levels. In this example scheme, the modulation of the first and second output nodes 102-1 and 102-2 is controlled by comparing respective target values Tgt1 and Tgt2 with two carrier waveforms C1 and C2. The target values Tgt1 and Tgt2 are derived from the input signal Sin, and, in this example, the target value Tgt1 corresponds to the required differential output voltage based on the input signal, within a normalised range of +1 to −1, where +1 corresponds to the maximum positive differential voltage output, i.e. +(VH−VL) and −1 corresponds to the maximum negative differential voltage output, i.e. −(VH−VL), and the target value Tgt2 is the inverse of the target value Tgt1, i.e. Tgt2=−Tgt1.

The carrier waveforms C1 and C2 collectively ramp across the normalised range with, in this example, carrier waveform C1 ramping from +1 down to a value R1 and back to +1 across a cycle period and carrier waveform C2 ramping up from −1 to the value R1 and then back to −1. FIG. 2 illustrates the carriers C1 and C2 as sawtooth waveforms, but it will be understood that triangle waveforms that ramp unidirectionally over the cycle period and then reset back to the starting value could be used and/or the ramping could be in the opposite sense, i.e. starting from R1. The value R1, within the range +1 to −1, corresponds to the level of the intermediate voltage within the range between the high-side and low-side voltages VH and VL. R1 can be set as:

R1=2(VM−VL)/(VH−VL)31 1 Eqn. 1

FIG. 2 illustrates an example where the intermediate voltage VM is lower than the midpoint voltage between VH and VL and thus the value R1 in this example is negative.

Each of the first and second output nodes 102-1 and 102-2 is modulated to the high-side voltage VH when the relevant target value is greater than the value of the first carrier waveform C1, is modulated to the intermediate voltage VM the relevant target value is lower than the value of the first carrier waveform C1 but higher than the second carrier waveform C2, and is modulated to the low-side voltage VL when the relevant target value is lower than the value of the second carrier waveform C2.

The left-hand side of FIG. 2 illustrates an example where the required differential output voltage is positive (assuming for the purposes of this disclosure that a positive differential output voltage corresponds to the first output node 102-1 being more positive than the second output node 102-2) and has a magnitude which is towards the upper end of the output range, i.e. the target value Tgt1 is towards the upper end of the normalised range (with the target value Tgt2 being equal and opposite). FIG. 2 also illustrates the resulting voltages V102-1 and V102-2 at the first and second output nodes 102-1 and 102-2 respectively over the course of the switching cycle and the resultant instantaneous differential voltage Vdiff between the first and second output nodes 102-1 and 102-2. For this signal level, it can be seen the first output node 102-1 is modulated between the high-side voltage VH and the intermediate voltage VM, whilst the second output node 102-1 1 is modulated between the intermediate voltage VM and low-side voltage VL.

The right-hand side of FIG. 2 illustrates an example where the required differential output voltage is positive, but near zero, and again illustrates the resulting voltages V102-1 and V102-1 and the instantaneous differential voltage Vdiff over the switching cycle. For this signal level, both of the first and second output nodes 102-1 and 102-2 are modulated between the high-side voltage VH and the intermediate voltage VM and are driven to the same voltage for a significant portion of the switching cycle, leading to an instantaneous differential voltage Vdiff which is zero for a significant part of the switching cycle.

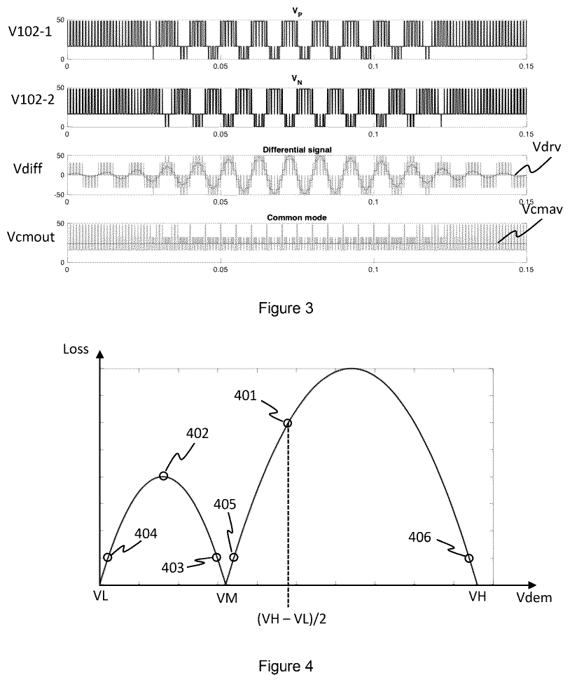

FIG. 3 illustrates switching waveforms for such a modulation scheme for an example where the high-side voltage was 48V, the intermediate voltage VM was 16V and the low-side voltage VL was ground. FIG. 3 illustrate the waveforms for a sinusoidal input signal Sin with an amplitude that ramps from near zero, to full scale and back to near zero and illustrates the voltages V102-1 and V102-2 at the first and second output nodes 102-1 and 102-2, the instantaneous differential voltage Vdiff and also the resulting differential drive voltage Vdrv across the load 101. FIG. 3 also shows the common-mode voltage Vcmout which is applied to the first and second output nodes 102-1 and 102-2. FIG. 3 illustrates the instantaneous common-mode voltage across the switching cycle and also the average common-mode voltage Vcmav, which corresponds to the common-mode component of the differential drive signal Vdrv.

The modulation scheme illustrated in FIG. 3 maintains a substantially constant average common-mode voltage Vcmav at a value which is equal to the midpoint of the high-side and low side voltages, i.e. at 24V in this example. It can be seen that the differential drive signal Vdrv can be generated across the full output range of the switching amplifier output with BD modulation, so avoiding either of the first or second output nodes 102-1 or 102-2 being modulated directly between the high-side and low-side voltages VH and VL.

However, for an input signal Sin at or near zero, each of the first and second output nodes 102-1 and 102-2 is, in the example of FIGS. 2 and 3, modulated between the high-side voltage VH and the intermediate voltage VM and it will be appreciated that the voltage difference between this pair of switching voltages is, in this example, greater than the voltage difference between the intermediate voltage VM and the low-side voltage VL. Thus, out of the two possible pairs of switching voltages, i.e. VH and VM or VM and VL, the pair of neighbouring voltages with the greatest voltage difference between is used at low signal levels. In addition, it will be understood that for signal levels at or near zero, each of the output nodes 102-1 and 102-2 will be modulated between the voltages VH and VM with a duty cycle that can be significant different from 0% (or 100%). Both of these factors can contribute to relatively significant inductor losses. One type of inductor loss is ripple loss, i.e. losses due to a ripple current in the inductor associated with the equivalent series resistance of the inductor. Another type of inductor loss is core loss, generally caused by eddy currents and hysteresis, which may typically be a greater source of loss. Both of these types of inductor losses tend to have a duty-cycle dependence.

For instance, consider just one of the T-bridges, say the T-bridge for driving the first output node 102-1 for a signal level such as illustrated on the right-hand side of FIG. 2, where the first output 102-1 node is modulated between the high-side voltage VH and intermediate voltage VM. In this case, the voltage VC1 maintained by the filter capacitor Cfil of the output filter 104 will correspond to the average output voltage at the first output node 102-1. Given any changes in this average output voltage due to a variation in the input signal Sin will occur slowly on the timescale of the switching cycle of the switching amplifier, the voltage VC1 can be considered to be substantially constant for this analysis. During the part of the switching cycle in which the first output node 102-1 is driven to the high-side voltage VH, there will be a positive voltage across the filter inductor Lfil and the inductor current will ramp positively. The change in inductor current ΔIL will depend on the voltage across the inductor, i.e. VH−VC, the value of the inductance Lfil and the duration for which the high-side voltage is applied, which has a dependence on the duty-cycle. The value VC also has a dependence on the duty-cycle and it can be shown that:

ΔIL=D.(1−D)(VH−VM))/L.fs Eqn. 2

It can thus be seen that the extent of the change in current, i.e. the ripple current, and hence the resultant ripple losses has a dependence on the duty-cycle with a relationship of D*(1−D) and is also proportional to the voltage difference between the switching voltages. Inductor core losses also tend to have the same shape and vary according to (D\hat{ }β)*((1−D)\hat{ }β), where β is an empirical value as will be understood by one skilled in the art.

FIG. 4 illustrates a plot of how inductor losses varies with voltage demand Vdem, i.e. the required average output voltage over the course of a switching cycle, for an output node which is modulated between the high-side voltage VH and intermediate voltage VM or between the intermediate voltage VM and the low-side voltage VL, in this case for an example where intermediate voltage VM is closer to the low-side voltage VL than to the high-side voltage VH. FIG. 4 illustrates that a voltage demand equal to midway between the low-side voltage VL and high-side voltage VH, which is illustrated as operating point 401, can result in a relatively high inductor losses.

As noted above, the common-mode component of the differential drive signal Vdrv is typically set to be midway between the high-side and low-side voltages so as to allow the full output range for the differential drive signal, i.e. to allow the differential drive signal to vary in the range from +(VH−VL) to −(VH−VL). However, whilst this signal swing is required for an input signal with an amplitude at or near full scale, for an input signal with only a small amplitude, or for a quiescent input signal, the common-mode voltage component can be set to a different value that results in reduced inductor losses.

For instance, consider that, for an input signal Sin with a low amplitude, the common-mode voltage component is set to a value midway between the intermediate voltage VM and the low-side voltage, in other words the voltage demand Vdem for the first output node for a differential drive voltage of zero would be equal to (VM−VL)/2. FIG. 4 illustrates this operating point as 402 and it can be seen that this voltage demand results in a lower loss than operating point 401.

Setting the common-mode voltage equal to (VM−VL)/2 would allow an input signal with an amplitude of (VM−VL) to be produced, whilst modulating each of the first and second output nodes between intermediate voltage VM and low-side voltage VL, and can provide reduced power losses at the signal levels compared to conventional approach of setting the common-mode voltage to be halfway between the high-side and low-side voltages. For larger amplitudes of input signal, the common-mode voltage can be dynamically varied in use to provide sufficient headroom for the required differential component.

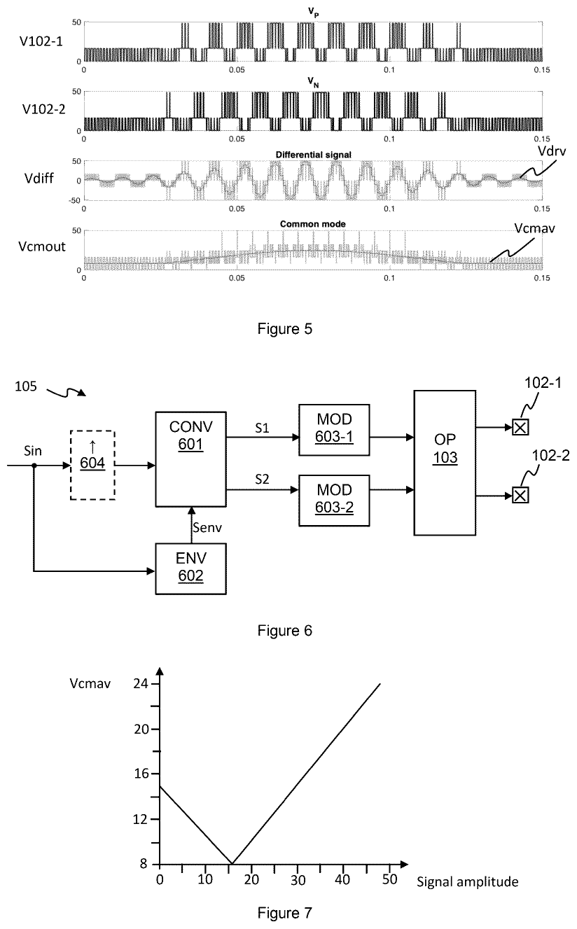

FIG. 5 illustrates example switching waveforms for such a modulation scheme for an example where, like that discussed with reference to FIG. 3, the high-side voltage was 48V, the intermediate voltage VM was 16V and the low-side voltage VL was ground. FIG. 5 again illustrates the waveforms for a sinusoidal input signal Sin with an amplitude that ramps from near zero, to full scale and back to near zero and illustrates the voltages V102-1 and V102-2 at the first and second output nodes 102-1 and 102-2 and the instantaneous differential voltage Vdiff and also the resulting differential drive voltage Vdrv across the load 101. FIG. 5 also shows the common-mode voltage Vcmout which is applied to the first and second output nodes 102-1 and 102-2 and the average common-mode voltage Vcmav, which corresponds to the common-mode component of the differential drive signal Vdrv.

It can be seen that in this case, for a low amplitude of input signal, each of the first and second output nodes 102-1 and 102-2 is modulated between the intermediate voltage VM and ground, with a common-mode voltage Vcmav of 8V (equal to VM/2 in this example where VL is ground). With this value of common-mode voltage, the differential drive signal Vdrv can vary within the range of +16V to −16V. As the amplitude of the input signal increases, and there is a need for a greater amount of signal swing for the differential drive signal, the value of the common-mode voltage Vcmav is dynamically increased, up to a value of 24V for a signal amplitude at or near full scale. This operation can thus advantageously reduce inductor losses at low or quiescent signal levels, compared to using a fixed common-mode voltage of 24V for all amplitude levels.

At least some embodiments of the present disclosure thus relate to switching amplifiers and to methods and apparatus for control of switching amplifiers, in which a common-mode voltage component may be dynamically controlled in use based on an indication of the input signal amplitude.

There are various ways in which the value of the common-mode voltage Vcmav may be dynamically varied in used. FIG. 6 illustrates one example a switching controller 105 according to an embodiment which allows for dynamic control of the common-mode voltage. The switching controller comprises a converter 601 which receives the input signal Sin and which converts the input signal into first and second signals S1 and S2, where:

S1=Scm+Sin/2, S2=Scm−Sin/2 Eqn 3

Scm is the target common-mode voltage component and is dynamically varied based on an indication of the amplitude of the input signal. The example of FIG. 6 illustrates that an envelope detector 602 may be arranged to receive the input signal Sin and determine an envelope value for this signal, which may be supplied to the converter 601 as an envelope signal Senv, although other arrangements such as peak detector or absolute value unit could be used in other examples. The converter 601 may determine an appropriate value of target common-mode voltage component based on the envelope value, for instance for the operation described with reference to FIG. 5, the target common-mode voltage component may be set to be 8V for an envelope value less 16V and may be set to be half the envelope value for envelope values greater than 16V.

The signals S1 and S2, which may effectively be used as the respective target values Tgt1 and Tgt2 discussed with reference to FIG. 2, can be supplied to respective modulators 603-1 and 603-1 to generate PWM control signals for switching the switches of the respective T-bridge of the output stage 103 to modulate the first and second output nodes 102-1 and 102-2.

Whilst the common-mode voltage Vcmav may thus be controlled to track with changes in the amplitude of the input signal Sin, in some embodiments it may be beneficial to limit the maximum rate of change of the common-mode voltage Vcamav, as rapid changes in the value of the common-mode voltage can lead to unwanted transients in the output path. In particular, a rapid change in the average common-mode voltage Vcmav applied to the output nodes each switching period, i.e. some high frequency component of the common-mode voltage of the output signal, can lead to ringing in the output path, in particular within the output filters 104 in the output path. For the common-mode voltage component Vcmav, the switching amplifier 100 can be seen as two parallel circuit branches connected between the common-mode voltage component and ground, each circuit branch comprising a resistance corresponding to the output resistance of the respective T-bridge in series with the filter inductor Lfil and capacitor Cfil. The two branches are connected by the load resistance, but impact of the load resistance RL on the common-mode response is generally minimal and thus can be ignored. This common-mode circuit is principally damped only by the output resistance of the T-bridges, and the output resistance of each T-bridge is generally low to avoid resistive losses in use. This means that the common-mode circuit is substantially undamped and rapid changes in the average common-mode voltage Vcmav can lead to unwanted ringing. Such ringing can lead to an increase in EMI and actually lead to an increase in inductor ripple current during the ringing, which can increase inductor losses. In addition, the output filters 104 on either side of the load 101 typically may exhibit some mismatch, particularly at high frequencies (in this case, approximately 1 k-20 kHz). This means that any rapid change in the common-mode voltage Vcmav could lead to some common-mode to differential conversion, which could lead to distortion.

To avoid these issues, the rate of change of the common-mode voltage may be limited, when possible, to a maximum rate of change, where the rate of change may be set with regard to a time constant of the common-mode circuit of the switching amplifier so as to not excite any significant ringing.

For a decrease in input signal amplitude, any corresponding change in the target common-mode value Scm may simply be subject to some rate limiting, e.g. by applying a suitable decay time constant to the target common-mode value Scm. In this case, for a sudden drop in signal amplitude the common-mode voltage value may provide more headroom than is needed for amount of the signal swing of the differential signal for a period of time, but the required differential drive signal can be produced without clipping.

However, for a sudden increase input signal amplitude, if the common-mode voltage Vcmav were only changed at the time of the increase in signal amplitude, it may be necessary to move the common-mode voltage Vcmav rapidly to allow for the necessary signal swing without clipping. In some implementations there may, therefore, be some degree of look-ahead of any changes in amplitude of the input signal so that, for a relatively sudden significant increase in signal amplitude, the common-mode voltage value can be moved over a period of time preceding the rise in signal amplitude so as to be at a suitable level when the increased signal level occurs.

There are various ways some degree of look-ahead of the amplitude of the input signal could be provided. For instance, in many switching amplifier designs there may be some inherent processing delay in a signal path of the amplifier that can be used to provide some look ahead.

FIG. 6 illustrates that the switching controller 105 may comprise an interpolator 604 configured to increase the sample rate of the input signal Sin. The interpolation by the interpolator 604 generally result in some propagation delay. FIG. 6 that the envelope detector may receive the input signal Sin prior to interpolation to determine the envelope value, which inherently provides some degree of look-ahead. FIG. 6 illustrates that interpolation is performed on the input signal Sin prior to conversion by the converter 601, but it will be understood that interpolation could instead be applied to the signals S1 and S2 downstream of the converter 601. It will also be understood that there may be other components, such as digital signal processor (DSP) in a signal path upstream or downstream of the converter 601 and which may additionally or alternatively result in some processing delay and the envelope detector 602 could receive the input signal from upstream of such other components.

Ideally the amount of look-ahead may be sufficient to allow the maximum possible variation common-mode voltage to be achieved without exceeding the desired maximum rate of change. However, this may not be possible for some implementations and the amount of look-ahead may not provide sufficient time to move the common-mode voltage by the maximum amount with a sufficiently low rate of change. In some applications, the amount of look ahead could be increased by deliberately including some additional delay in the processing path, but in at least some applications this may be undesirable for latency reasons.

In the event that the amount of look-ahead does not provide sufficient time to move the common-mode voltage by the required amount without exceeding the maximum rate of change, the maximum rate of change may be exceeded, and moving the common-mode voltage as slowly as possible given the amount of look-ahead may still reduce the amount of ringing. In some implementations, the amount of ringing could be suppressed by applying some damping during the period of change of the common-mode voltage. Damping could be applied, for instance, by increasing the output resistance of the switching amplifier, e.g. by selectively connecting a resistance into an output path for the T-bridge, or by implementing at least some of the switches of the T-bridge as split switches comprising two or more separate switch elements in parallel. During normal operation, the whole of the split-switch, i.e. all of the switch elements, may be turned on together to operate the switch in a low resistance on-state. However, when damping is required, only part of the split switch, e.g. just one of the switch elements, could be turned on when required, so as to operate the switch in a high resistance on-state.

In some implementations, in the event that the amount of look-ahead does not provide sufficient time to move the common-mode voltage by the required amount without exceeding the maximum rate of change, the increase in signal amplitude could be limited, e.g. by applying compression to the input signal Sin to limit the amplitude that that which can be achieved, without clipping, given the present value of the common-mode voltage Vcmav, or otherwise delaying the increase in signal amplitude. For a change in amplitude that results from some change in user or system-controlled gain, e.g. a change in volume that results in an increase in amplitude, the change in gain could be delayed until the common-mode voltage Vcmav has reached a level where the required signal amplitude can be generated. The converter 601 may therefore be configured to controllably apply compression to the input signal, ither itself or via some compressor (not separately illustrated). It will be appreciated that compression may only be required for a sudden, large increase in signal amplitude.

Referring back to FIG. 5, the operation described uses a fixed value of common-mode voltage Vcmav which is midway between the low-side voltage VL and intermediate voltage VM, for low signal amplitudes, whilst both output nodes are modulated between VM and VL. This allows for the maximum signal swing of the differential drive signal using these switching voltages. However, other values of common-mode voltage Vcmav could be used for a quiescent signal level to reduce the power losses even further.

For example, the common-mode voltage Vcmav could be set to be equal to intermediate voltage VM, e.g. to 16V for the example given above, so that a quiescent signal level corresponds to both the first and second output nodes 102-1 and 102-2 being driven to the intermediate voltage VM for the whole of the switching cycle. However, setting the common-mode voltage Vcmav being equal to the intermediate voltage VM would mean that any differential signal component would result in the first output node 102-1 being modulated between the high-side voltage VH and intermediate voltage VM for the positive part of the signal and being modulated between the intermediate voltage VM and low-side voltage for the negative part of the signal-with the reverse being the case for the second output node 102-2. This would involve swapping between the different pairs of switching voltages at low signal amplitudes, which can be disadvantageous as any distortion due to swapping between the different pairs of switching voltages will have a greater impact at low signal amplitudes.

Therefore, it may be advantageous to set the common-mode voltage Vcmav for a quiescent signal level to be near to the intermediate voltage VM, but with sufficient headroom to allow some small signal swing, before the switching voltages used to modulate either of the output nodes would be changed. For example, for the example discussed above, where the intermediate voltage is 16V, the common-mode voltage could be set to be at a value of, say 15V, e.g. an operating point 403 as illustrated in FIG. 4. Setting the common-mode voltage Vcmav to such a level would mean that the ripple current associated with a quiescent signal would be significant lower than either of operating points 401 or 402, with consequent savings in inductor losses, and a differential signal component in the range of +2V to −2V could be accommodated with both outputs nodes being modulated between VM and VL, i.e. between 16V and ground in this example.

In this case, to maximise the operating range over which both output nodes are modulated between VM and VL, the common-voltage Vcmav could be reduced towards (VM−VL)/2, i.e. from 15V to 8V in this example, with increasing amplitude of the input signal Sin. Once the common-mode voltage value of (VM−VL)/2 is reached, any further increase in signal amplitude may result in an increase in the common-mode voltage Vcmav, to provide sufficient headroom for the required differential component, and the modulation of the output nodes may swap to modulation between VH and VM when required. The common-mode voltage Vcmav may then be increased with increasing signal amplitude up to a value of (VH−VL)/2, i.e. 24V this example, to allow for a full-scale differential drive signal Vdrv.

FIG. 7 illustrates how the common-mode voltage Vcmav may be varied with amplitude of the input signal Sin (expressed in terms of the resulting differential drive signal amplitude) and FIG. 8 illustrates the resulting switching waveforms for the same input signal as illustrated in the FIGS. 3 and 5. It can be seen that for an input signal amplitude near zero, each of the first and second output nodes 102-1 and 102-2 is modulated between the intermediate voltage VM and ground, with a common-mode voltage Vcmav of 15V, near to the intermediate voltage VM of 16V. This will provide a low inductor ripple current and thus limits inductor losses. As the input signal amplitude increases, the common-move voltage Vcmav is dynamically reduced until the common-mode voltage Vcmav reaches 8V. A further increase in signal amplitude results in the common-mode voltage Vcmav being increased, with one of the first and second output nodes 102-1 and 102-2 being modulated between VH and VM at the peak signal excursion. The common-mode voltage Vcmav may be varied up to 24V for a full-scale input signal amplitude.

Referring back to FIG. 4, setting the common-mode voltage Vcmav at operating point 403 can thus provide significantly reduced power savings for quiescent and low-amplitude input signals. It will be clear that a similar power saving could be achieved by instead setting the common-mode voltage Vcmav for low signal levels to operating point 404, which in this example corresponds to a common-mode voltage of 1V. This would provide the same inductor ripple current for a differential drive signal of zero and would again allow for some small signal swing. In this case, as the amplitude of the input signal increased, the common-mode voltage Vcmav would be increased accordingly. Setting the common-mode voltage for quiescent or low amplitude signals at operating point 404, which is close to the low-side voltage VL could be beneficial in terms of power supply noise, e.g. PSSR, when the low-side voltage is ground. At low signal amplitude, the first and second output nodes 102-1 and 102-2 would spend most of the switching cycle modulated to ground, which typically is a relatively clean supply voltage, i.e. it has less power supply noise than the other switching voltages. However, the amount of movement of the common-mode voltage for a sudden large increase in signal amplitude may be greater and, as noted above, it may be desirable to limit the rate of change of the common-mode voltage. Thus, for example, if there was a relatively sudden change from a quiescent input signal to an input signal with an amplitude of 40V say, then for operation with a common-mode voltage for low-amplitudes at operating point 404, there would be a need to vary the common-mode voltage from 1V to 20V, whereas for operation with a common-mode voltage for low-amplitudes at operating point 403, the common-mode voltage would only need to be changed from 15V to 20V.

It will also be noted that a similar ripple current for quiescent input signals could be achieved by setting the common-mode voltage Vcmav for small signals to be at operating point 405, which is near to, but greater than, the intermediate voltage or operating point 406, which is near to the high-side voltage VH. Setting the common-mode voltage Vcmav at operating point 406 may have similar issues in terms of increasing the extent of change in common-mode voltage required on a change in signal amplitude (but in this case the common-mode voltage Vcmav would be reduced to provide the headroom for the required signal swing) but likely without the benefits of PSSR, so this may not be a preferred option. Operating with a common-mode voltage for low-amplitudes at operating point 405, may however provide similar benefits as the described operation at operating point 403, but in this case for small signal amplitudes, both of the first and second output nodes 102-1 and 102-2 will be modulated between the high-side voltage VH and the intermediate voltage VM. In some applications, this may be beneficial in terms of managing the power which is drawn, in use, from at least one of the voltage supplies providing the switching voltages.

For example, in some applications there may be a power budget as to the power that can be drawn from at least one of the power supplies and it may be desirable to manage the power drawn, in use from such a supply.

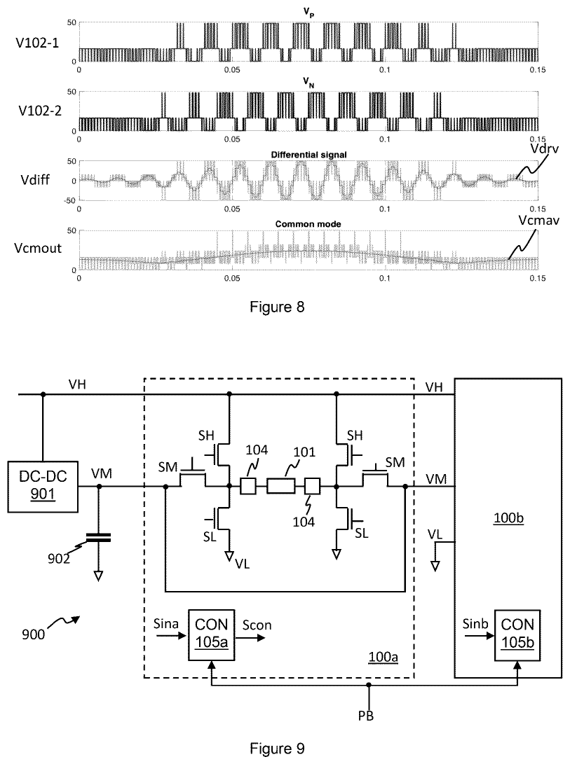

For example, FIG. 9 illustrates an amplifier system 900 comprising multiple switching amplifiers that share the same voltage supplies, for instance which may be formed as part of the same integrated circuit. FIG. 9 illustrates a first switching amplifier 100a for driving a load 101 which has the same general structure as described above with reference to FIG. 1. FIG. 9 also illustrates a second switching amplifier 100b, which again may have the same general structure (but the details of the second switching amplifier are omitted for clarity). The amplifier system 900 may thus be a multichannel system, e.g. a multichannel audio system, with a respective switching amplifier for each channel.

FIG. 9 illustrates that the amplifier system 900 may have an input power rail that provides a voltage which, in this example, is used as the high-side voltage VH for the switching amplifiers 100a and 100b. A DC-DC converter 901, for instance such as an inductive buck-converter or charge pump, is configured to generate the intermediate voltage VM from the input power rail. The intermediate voltage VM may be maintained by a capacitance 902 at the output of the DC converter 901. In this example, the low-side voltage VL is ground.

In use, each of the switching amplifiers 100a and 100b is controlled by a respective switch controller 105a and 105b to drive its respective load 101 based on a respective input signal Sina and Sinb. The switch controllers 105a and 105b may be configured to operate as described above and thus may control the common-mode voltage Vcmav of the relevant switching amplifier 100a or 100b to limit the inductor losses at low signal amplitudes. In the system of FIG. 9, the switch controllers 105a and 105b may also be configured to control the common-mode voltage Vcmav to manage the power draw from the DC-DC converter 901. For example, a power budget may be determined local to that system and the power draw across all the different channels may be used by the controllers 105a and 105b to determine to control the common-mode voltage Vcmav of one more channels, so as to stay within the power budget.

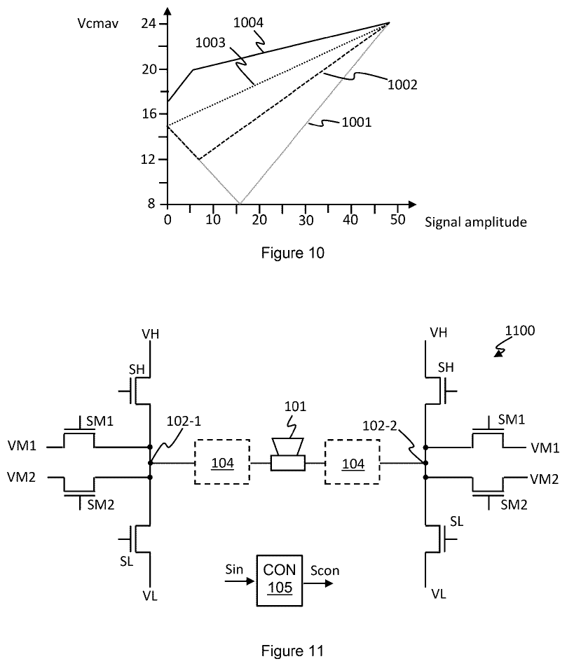

FIG. 10 illustrates some examples of different ways in which the common-mode voltage Vcmav could be controlled so as to vary the power draw from the DC-DC converter 901. FIG. 10 illustrates various different possible transfer characteristics between the signal amplitude and common-mode voltage Vcmav for the example where the high-side voltage VH is 48V, the intermediate voltage VM is 16V and the low-side voltage VL is ground.

A first transfer characteristic 1001 is the same as discussed above with reference to FIG. 7. As noted above, this approach, involves the common-voltage Vcmav for quiescent signals being set close to, but lower than, the intermediate voltage VM, e.g. at an operating point 403 such 15V. The common-mode voltage Vcmav then reduces with increasing signal amplitude until the common-mode voltage Vcmav become equal to (VM−VL)/2, i.e. to 8V in the example, and then increases with further increases in signal amplitude. This approach maximises the use of intermediate voltage VM and low-side voltage VL as the pair of switching voltages used for modulating the output nodes and thus maximises the power draw from the DC-DC converter 901—but may provide the lowest inductor losses.

A second transfer characteristic 1002 again uses the operating point 403, e.g. 15V, for quiescent signals and reduces the common-mode voltage with increasing signal amplitude. However, for the second transfer characteristic 1002, the common-mode voltage Vcmav is not reduced all the way to (VM−VL)/2. FIG. 10 illustrates, for example, the common-mode voltage Vcmav may be reduced to a minimum value of 12V, which, for this example, would allow a differential drive signal with an amplitude of up to 8V to be generated whilst modulating the output nodes using the intermediate voltage VM and low-side voltage VL only. For greater signal amplitudes, the common-mode voltage Vcmav is increased which means that one of the output nodes will be modulated between the high-side voltage VH and the intermediate voltage for the peak signal excursion, and this pair of switching voltage will be increasingly used as the signal amplitude increases further. This operation draws less power from the DC-DC converter 901 than operation according to the first transfer characteristic 1001. It will be noted that during the switching cycle in which an output node is modulated between the high-side voltage VH and the intermediate voltage VM, the power which is drawn from the supplies will predominantly be drawn from the high-side voltage rail, and the power draw from the DC-DC converter 901 may be low or negligible.

A third transfer characteristic 1003 again uses the operating point 403 for quiescent signals, but in this case any increase in the signal amplitude from zero results in an increase in the common-mode voltage. This means that the intermediate voltage VM from the DC-DC converter is used to provide power only for very low signal amplitudes, and at even relatively low signal amplitudes, most of the power may be drawn from the input voltage rail. However, this operation does involve swapping between the different pairs of switching voltages at low signal amplitudes, of the order of 1V, and as mentioned above, this can be disadvantageous as any distortion due to swapping between the different pairs of switching voltages will have a greater impact at low signal amplitudes.

A fourth transfer characteristic 1004 uses the operating point 405 for quiescent signals and thus operates with a common-mode voltage Vcmav for such signals which is near to, but greater than the intermediate voltage VM, e.g. a voltage of around 17V in this example. In this case, for quiescent input signals, the output nodes will be modulated between the high-side voltage VH and the intermediate voltage VM and there will be no significant power draw from the DC converter even for quiescent signal levels. As the signal amplitude increases, the common-mode voltage Vcmav is increased. For this example of the fourth transfer characteristic 1004, the common-mode voltage varies with a first gradient over a first range of signal amplitude, in this example up to a signal amplitude of 8V, so that a signal of that amplitude can be generated by modulating both output nodes between VH and VM. This avoids any swapping of the switching voltages used for modulation at low signal amplitudes, below 8V in this example. For higher signal amplitudes, above 8V in this example, the common-mode voltage Vcmav may vary with signal amplitude with a second gradient, so as to reach the common-mode voltage value of 24V at a signal amplitude of 48V. This may generally minimise inductor losses, whilst predominantly drawing power from the input supply rail at the high-side voltage VH.

It will be understood that the transfer characteristics illustrated in FIG. 10 shows the desired common-mode voltage for a given signal amplitude but, as noted above, some limiting may be applied to limit the rate of change of the common-mode voltage and/or the common-mode voltage may be varied based on some look-ahead of what the signal amplitude will be and thus, in use, the actual relationship between common-mode voltage and signal amplitude could vary.

It will also be understood that the transfer characteristics illustrated in FIG. 10 are just some possible examples and other transfer characteristics may be implemented. It will also be appreciated that, in some cases, there may be a range of signal amplitudes for which the common-mode voltage Vcmav is not varied.

The switch controllers 105a and 105b may be configured to implement a desired transfer characteristic so as to manage power draw from DC-DC converter 901. For example, each of the switch controllers 105a and 105b may be configured to operate to control the common-mode voltage according to the second transfer characteristic 1002 so as to provide some power savings but limit the power draw on the DC-DC converter. In some implementations, one or both of the switch controllers 105a and 105b may be configured to adopt an appropriate transfer characteristic based on an indication of the available power from the DC-DC converter and/or the loading of the DC-DC converter. For example, the switch controllers 105a and 105b may each receive an indication of an allowable power budget for power draw from the DC-DC converter, which may take into account any power draw on the DC-DC converter 901 from other circuitry (not illustrated in the FIG. 9) and may operate collectively so as to manage the power draw on the DC-DC converter. For instance, if the power budget allows, both switch controllers may operate according to the first transfer characteristic. If however, there are constraints on the power which may be drawn from the DC-DC converter, one or both of the switch controllers 105a and 105b may swap to operate with an appropriate one of the second, third or fourth transfer characteristics.

It should be noted that the examples have been described for a switching amplifier operable with three different switching voltage and where the intermediate voltage VM is closer to the low-side voltage VL than the high-side voltage VH. Similar principles would apply if the intermediate voltage VM were closer to the high-side voltage VH than the low-side voltage VL, but this would change the profile of inductor loss with voltage demand, e.g. the relationship illustrated in FIG. 4 may be reversed, and in this case the consideration of the advantages of different operating points for the common-mode voltage for quiescent input signal and the transfer characteristic between signal amplitude and common-mode voltage may be different, but the same general principles would apply.

The same principles would also apply to a switching amplifier in which the output nodes can, in at least one mode of operation, be selectively modulated between more than three different switching voltages.

For example, FIG. 11 illustrates one example of a switching amplifier 1100 (where similar components as discussed with reference to FIG. 1 are identified by the same reference numerals) where each the first and second output nodes 102-1 and 102-2 may be selectively connected to any of four different switching voltages, a high-side voltage VH via switch SH, a low-side voltage VL via switch SL or any of two different intermediate voltages VM1 and VM2, which are different to one another and are at voltage levels between VH and VL, via respective switches SM1 and SM2. It will be understood, however, that FIG. 11 illustrates just one possible switch arrangement for the switching amplifier 1100, and other arrangements may be implemented. In general, there is a respective switching path, which may comprise one or more switches, for connecting the output node 102-1 and 102-2 to each switching voltage, and at least some parts of the switching paths for different switching voltages could be shared.

The switching amplifier 1100 may be operable in a four-level BD type mode, such each of the first and second output nodes may be selectively modulated between any selected pair of neighbouring switching voltages, e.g. between the high-side voltage VH and the first intermediate voltage VM1, between the first and second intermediate voltages VM1 and VM2 or between the second intermediate voltage VM2 and the low-side voltage VL. The switch controller 105 may control modulation of the first and second output nodes 105 by comparing a suitable target value for the modulation of the relevant output nodes with three different carrier waveforms which ramp across appropriate parts of the normalised output range.

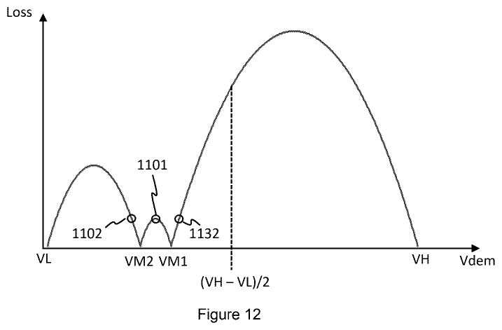

FIG. 12 illustrates a plot of inductor losses against voltage demand from an output node for an example, where the high-side voltage VH is 48V, the first intermediate voltage VM1 is 16V, the second intermediate voltage is 12V and the low-side voltage is ground. Again, various different operating points for the common-mode voltage Vcmav for a quiescent input signal may be considered, with different transfer characteristics for variation of the common-mode voltage with signal amplitude.

For instance, the operating point illustrated as 1101, which is midway between the first and second intermediate voltages VM1 and VM2, e.g. 14V in this example, may be used for the common-mode voltage Vcmav for quiescent input signal. This means that both output nodes are modulated between the first and second intermediate voltages for a quiescent input signal, which can provide a low losses, and there is headroom for a signal amplitude of 4V without needing to change the switching voltage used for modulation. For higher signal amplitudes the common-mode voltage may be significant reduced so as to transition to modulating both output nodes between the voltages VM2 and VL-although the rate of change of the common-mode voltage may, in practice, be limited to avoid exciting any ringing effects. For higher signal amplitudes, the common-mode voltage Vcmav may varied to a higher value to provide sufficient headroom for the differential signal component.

An alternative could be to operate with operating point 1102, which is slightly lower than the second intermediate voltage VM2, for quiescent input signals. Both output nodes would thus be modulated between the voltages VM2 and VL for quiescent signal levels. The common-mode voltage Vcmav could then be reduced with increasing signal amplitude, e.g. towards a value midway between VM2 and VL, before being increased wit further increases in signal amplitude. Another alternative could be to operate with operating point 1103, which is slightly higher than the first intermediate voltage VM1, for quiescent input signals. Both output nodes would thus be modulated between the voltages VH and VM1 for quiescent signal levels. The common-mode voltage Vcmav could then be increased with increasing signal amplitude. The relevant operating point for a quiescent signal and the transfer characteristic between signal amplitude and common-mode voltage may be selected based on any power limitation of the relevant voltage supplies as discussed above.

In some implementations, some voltages may only be used for modulation at certain amplitude levels. For instance, for the example discussed above where the first and second intermediate voltages VM1 and VM2 are relatively close together, e.g. 16V and 12V, modulating the output nodes between these voltages may be used for relatively low signal amplitudes. For instance, for signal amplitudes below 4V, the first and second output nodes 102-1 and 102-2 may be modulated between the first and second intermediate voltages VM1 and VM2, but for greater signal amplitudes the switch controller could swap to a three-level modulation mode using just one of the intermediate voltages VM1 or VM2, e.g. the switch controller may modulate the output nodes between VH and VM1 or between VM1 and VL in a similar manner as the three level embodiments discussed above. In the three-mode mode the active set of switching voltages used for modulating the output nodes may thus be limited to three switching voltages. This can avoid the need to swap the switching voltages used for modulation of an output node from VH and VM1, to VM1 and VM2 and then to VM2 and VL in a relatively short period of time for signals with a relatively high amplitude. The choice of which of the first and second intermediate voltages VM1 and VM2 to use in the three-level mode could be based on the power budget and/or loading of the voltage supplies providing VM1 and VM2.

Alternatively, the switch controller could operate in a first three-level mode, using the first and second intermediate voltages VM1 and VM2 and one of the high-side and low-side voltages VH and VL for signal amplitude in a first range, and then swap to a second three-level mode using the high-side and low-side voltages VH and VL and one of the first and second intermediate voltages VM1 and VM2 for a second, higher, range of signal amplitudes.

The embodiments above have been described with reference to a switching controller for controlling switching of switching of an output stage of the switching amplifier. In some embodiments, at least some of the switches of the switching amplifier may be implemented as part of a separate integrated circuit (IC) to that comprising the switch controller. This can allow each integrated circuit to be more optimised for its purpose and, in particular, can allow for different material systems to the be for the different integrated circuits. For instance, for high power applications it can be advantageous to implement at least some of the switches in a compound semiconductor material system such as a Gallium Nitride based IC, whereas it may be more convenient to implement the switch controller, and any other signal processing or amplifier control circuitry, in a conventional silicon-based IC. Using two different integrated circuits can allow each circuit to be optimized for its intended use in this way. In some examples, there may therefore be a first IC which implements the output bridge and a second IC for controlling the output bridge.

Embodiments of the present disclosure thus relate to control methods and apparatus for switching amplifiers configured to drive a load in a BTL configuration based on an input signal, where, in use, each of first and second output nodes can be modulated between selected voltages of a set of at least three switching voltages and in which the switching of the switching amplifier is controlled so as to dynamically vary a common-mode voltage component of the output of the switching amplifier based on the amplitude of the input signal. The common-mode voltage component may be dynamically varied so as to reduce losses in a filter inductor where possible and/or to manage power draw from the voltage supplies providing the switching voltages.

Embodiments may be implemented in a host device, which could be a portable and/or battery powered host device such as a mobile computing device for example a laptop, notebook or tablet computer, or a mobile communication device such as a mobile telephone, for example a smartphone. The device could be a wearable device such as a smartwatch. The host device could be a games console, a remote-control device, a home automation controller or a domestic appliance, a toy, a machine such as a robot, an audio player, a video player. Embodiments may be implemented as part of a system provided in a home appliance or in a vehicle or interactive display. There is further provided a host device incorporating the above-described embodiments.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A controller for controlling an output stage of a switching amplifier to drive a load connected between first and second output nodes with a differential drive signal based on an input signal, wherein:
the controller is configured to be operable to control the output stage to modulate each of first and second output nodes between respective selected switching voltages in switching cycles to generate the differential drive signal, wherein the selected switching voltages are neighbouring switching voltages selected from a set of at least three different switching voltages and wherein a voltage difference between at least one pair of neighbouring switching voltages of the set is different to a voltage difference between at least one other pair of neighbouring switching voltages of the set; and
the controller is configured to control the modulation of the first and second output nodes to dynamically control a common-mode voltage applied to the first and second output nodes based on an indication of amplitude of the input signal.

2. The controller of claim 1 wherein the controller is configured to be operable to control the common-mode voltage to have a first value for an input signal amplitude which is zero, where the first value is not equal to a midpoint voltage value which is midway between the highest and lowest voltages of the set of at least three switching voltages.

3. The controller of claim 2 wherein the first value is selected such that the extent of a ripple current generated by modulating the first and second output nodes with the first value of common-mode voltage is lower than a ripple current that would be generated by modulating the first and second output nodes with a common-mode voltage equal to the midpoint voltage value.

4. The controller of claim 2 wherein, for at least a first range of non-zero input signal amplitude, the controller is configured to dynamically vary the common-mode voltage with variation in input signal amplitude.

5. The controller of claim 4 wherein the controller is configured to vary the common-mode voltage so that the differential drive signal based on the input signal can be generated without clipping.

6. The controller of claim 4 wherein the controller is configured to limit the rate of change of the common-mode voltage to not exceed a maximum rate of change.

7. The controller of claim 4 wherein the controller is configured to apply signal limiting to the input signal so as to limit any increase in signal amplitude that would require a rate of change of the common-mode voltage that would exceed a maximum rate of change.

8. The controller of claim 4 wherein the controller receives a look-ahead indication of what the input signal amplitude will be and is configured to dynamically vary the common-mode voltage based on said look-ahead indication.

9. The controller of claim 4 wherein the controller is further configured to control the common-mode voltage applied to the first and second output nodes based on a power budget for power draw from a first power supply for providing one of the switching voltages of the set.

10. The controller of claim 9 wherein the controller is configured to receive an indication of loading of the first power supply.

11. The controller of claim 4 wherein the first value of common-mode voltage is selected such that modulating the first and second output nodes with the first value of common-mode voltage for an input signal of zero amplitude results in power being drawn from the first power supply and the controller is further operable to control the common-mode voltage to have a second, different, value for an input signal amplitude which is zero, wherein the second value of common-mode voltage is selected such that modulating the first and second output nodes with the second value of common-mode voltage for an input signal of zero amplitude results in substantially no power being drawn from the first power supply.

12. The controller of claim 1 wherein the said set of at least three switching voltages comprises at least a first voltage V1, a second voltage V2 and third voltage V3, wherein V1>V2>V3 and V2 is closer to V3 than V1.

13. The controller of claim 12 wherein the controller is configured to be operable to control the common-mode voltage to have a first value for an input signal amplitude which is zero, where the first value is between V2 and V3.

14. The controller of claim 13 wherein the first value is midway between V2 and V3.

15. The controller of claim 13 wherein the first value is closer to V2 than to V3.

16. The controller of claim 15 wherein:
for a first range of input signal amplitude, the controller is configured to dynamically vary the common-mode voltage with variation in input signal amplitude so to reduce the common-mode voltage from the first value to a second value with increasing signal amplitude, where the second value is equal to or greater than a voltage midway between V2 and V3; and
wherein for a second range of greater input signal amplitude, the controller is configured to dynamically vary the common-mode voltage with variation in input signal amplitude so to increase the common-mode voltage from the second value to a third value with increasing signal amplitude, where the third value is equal to a voltage midway between V1 and V3.

17. A switching amplifier circuit comprising the controller of claim 1 and an output stage.

18. A controller for controlling an output stage of a switching amplifier to drive a load connected between first and second output nodes with a differential drive signal based on an input signal, wherein:
the controller is configured to be operable to control the output stage to modulate each of first and second output nodes between respective selected switching voltages of a set of at least three switching voltages in switching cycles to generate the differential drive signal; and
the controller is configured to control the modulation of the first and second output nodes so to dynamically vary a common-mode voltage applied to the first and second output nodes with input signal amplitude over at least a first range of input signal amplitude.

19. A controller for controlling an output stage of a switching amplifier to drive a load connected between first and second output nodes with a differential drive signal based on an input signal, wherein:
the controller is configured to be operable to control the output stage to modulate each of first and second output nodes between respective selected switching voltages of a set of at least three switching voltages in switching cycles to generate the differential drive signal; and
the controller is configured to control the modulation of the first and second output nodes so to dynamically vary a common-mode voltage applied to the first and second output nodes based on a power budget for power draw from a first power supply for providing one of the switching voltages of the set of at least three switching voltages.

20. A controller for controlling a multichannel driver having a plurality of channels, each channel comprising a respective switching amplifier for driving a respective load connected between respective first and second output nodes with a respective differential drive signal based on a respective input signal, wherein:
the controller is configured to be operable to control each switching amplifier to modulate each of first and second output nodes between respective selected switching voltages of a set of at least three switching voltages in switching cycles to generate the differential drive signal; and
the controller is configured to control at least one of the switching amplifiers so to dynamically vary a common-mode voltage applied to the respective first and second output nodes to control an overall power draw from a first power supply for providing one of the switching voltages of the set of at least three switching voltages from all of the switching amplifiers.
